(19) United States
(12) Patent Application Publication
(10) Pub. No.: US 2024/0243040 A1
(43) Pub. Date: Jul. 18, 2024

(54) LEADFRAME

(71) Applicant: Danfoss Silicon Power GmbH, Flensburg (DE)

(72) Inventor: Tobias APPEL, Flensburg (DE)

(21) Appl. No.: 18/577,508

(22) PCT Filed: Jul. 7, 2022
(86) PCT No.: PCT/EP2022/068872

§ 371 Date: Jan. 8, 2024

(30) Foreign Application Priority Data
Jul. 9, 2021 (DE) 10 2021 117 822.3

(51) Int. Cl. H01L 23/495; H01L 21/48; H01L 21/56; H01L 23/31

(52) U.S. Cl. CPC H01L 23/49541; H01L 21/4825; H01L 21/4842; H01L 21/56; H01L 23/3107

(57) ABSTRACT

A method is described forming a first sub-leadframe having one or more first connection terminals; forming a second sub-leadframe having one or more second connection terminals; joining the first and second sub-leadframes to form a leadframe such that at least some of the first connection terminals overlap at least some of the second connection terminals.

### CROSS-REFERENCE TO RELATED APPLICATIONS

This application is a National Stage application of International Patent Application No. PCT/EP2022/068872, filed on Jul. 7, 2022, which claims priority to German Patent Application No. 10 2021 117 822.3, filed Jul. 9, 2021, each of which is hereby incorporated by reference in its entirety.

### TECHNICAL FIELD

The present specification relates to a leadframe, for example, comprising to a leadframe that forms part of a power module.

### BACKGROUND

Many methods of manufacturing leadframes are known in the art. However, there remains a need for further developments in this field.

### SUMMARY

In a first aspect, this specification describes a method comprising: forming a first sub-leadframe having one or more first connection terminals; forming a second sub-leadframe having one or more second connection terminals; joining the first and second sub-leadframes to form a leadframe such that at least some of the first connection terminals overlap at least some of the second connection terminals.

In some examples, the first sub-leadframe further comprises a supporting frame, wherein the first and second sub-leadframe are joined using the supporting frame.

In some examples, at least some of the first connection terminals are connected to form a first busbar.

In some examples, at least some of the second connection terminals are connected to form a second busbar.

In some examples, the first and second sub-leadframes are joined by dovetailing.

In some examples, the first sub-leadframe and/or the second sub-leadframe is/are formed by stamping.

Some examples further comprise placing the leadframe onto a substrate; and electrically connecting the leadframe to circuit elements mounted on the substrate. One or more of a number of methods may be used to electrically connect the leadframe to circuit elements mounted on the substrate. Such methods may include ultrasonic welding, laser welding, sintering, gluing or induction soldering.

Some examples further comprise encapsulating the leadframe and the substrate, leaving the first and second connection terminals exposed.

Some examples further comprise removing some or all of the supporting frame such that the first and second connection terminals of the leadframe do not make physical or electrical contact.

In some examples, one of the first connection terminals comprises a plurality of first fingers; one of the second connection terminals comprises a plurality of second fingers; and the first and second fingers are provided in an alternating pattern.

In a second aspect, this specification describes a leadframe comprising: a first sub-lead frame comprising one or more first connection terminals; a second sub-lead frame comprising one or more second connection terminals, wherein the first and second sub-leadframes are joined such that at least some of the first connection terminal overlap at least some of the second connection terminals.

In some examples, the first sub-leadframe further comprises a supporting frame, wherein the first and second sub-leadframe are joined using the supporting frame.

In some examples, at least some of the first connection terminals of the leadframe are connected to form a first busbar; and/or at least some of the second connection terminals of the leadframe are connected to form a second busbar.

In some examples, one of the first connection terminals comprises a plurality of first fingers; one of the second connection terminals comprises a plurality of second fingers; and the first and second fingers are provided in an alternating pattern.

In some examples, some or all of the supporting frame is configured to be removed such that the first and second connection terminals of the leadframe do not make physical or electrical contact.

In a third aspect, this specification describes a power module comprising: a leadframe described with respect to the second aspect; and a substrate onto which the leadframe is placed, wherein the substrate comprises circuit elements electrically connected to said substrate. One or more of a number of methods may be used to electrically connect the leadframe to circuit elements mounted on the substrate. Such methods may include ultrasonic welding, laser welding, sintering, gluing or induction soldering.

In some examples, the power module further comprises an encapsulation material encapsulating the leadframe and the substrate, leaving the first and second connection terminals exposed.

In a fourth aspect, this specification describes a computer-readable medium having computer executable instructions adapted to cause a 3D printer or additive manufacturing apparatus to form some or all of an apparatus according to the method as described above with reference to the first aspect, a leadframe as described above with reference to the second aspect, or a power module as described above with reference to the third aspect.

### BRIEF DESCRIPTION OF THE DRAWINGS

Example embodiments will now be described, by way of example only, with reference to the following schematic drawings, in which:

FIG. 1 is a three-dimensional view of a circuit;

FIG. 2 is a side view of the circuit of FIG. 1;

FIG. 3 is a flowchart of an algorithm in accordance with an example embodiment;

FIG. 4 is a view from above of a sub-leadframe in accordance with an example embodiment;

FIG. 5 is a three-dimensional view of the sub-leadframe of FIG. 4 in accordance with an example embodiment;

FIG. 6 is a view from above of a sub-leadframe in accordance with an example embodiment;

FIG. 7 is a three-dimensional view of the sub-leadframe of FIG. 6 in accordance with an example embodiment;

FIG. 8 is a view from above of a leadframe in accordance with an example embodiment;

FIG. 9 is a three-dimensional view of the leadframe of FIG. 8 in accordance with an example embodiment;

FIG. 10 is a side view of the leadframe of FIG. 8 in accordance with an example embodiment;

FIG. 11 is a three-dimensional view of a leadframe in accordance with an example embodiment;

FIG. 12 is a flowchart of an algorithm in accordance with an example embodiment;

FIG. 13 is a three-dimensional view of a circuit in accordance with an example embodiment;

FIG. 14 is a view from above of sub-leadframes in accordance with an example embodiment;

FIG. 15 is a view from above of a leadframe in accordance with an example embodiment;

FIG. 16 shows a switching module used in an example embodiment; and

FIG. 17 is a block diagram of an inverter circuit used in example embodiments.

### DETAILED DESCRIPTION

The scope of protection sought for various embodiments of the invention is set out by the independent claims. The embodiments and features, if any, described in the specification that do not fall under the scope of the independent claims are to be interpreted as examples useful for understanding various embodiments of the invention.

In the description and drawings, like reference numerals refer to like elements throughout.

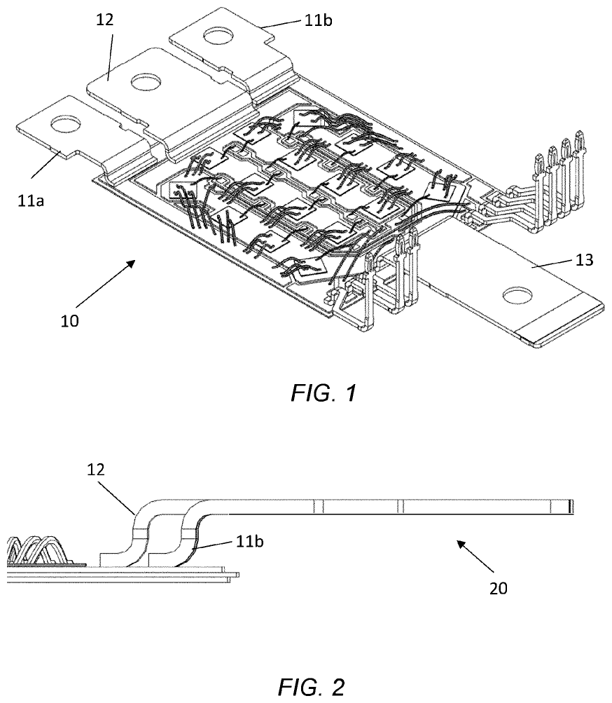

FIG. 1 is a three-dimensional view of a circuit (such as a power module), indicated generally by the reference numeral 10. The circuit 10 comprises a leadframe with first connection terminals 11a and 11b (e.g. negative direct current (DC) terminals), second connection terminal 12 (e.g. positive DC terminal), and alternating current (AC) terminal 13. The circuit 10 further comprise a plurality of circuit elements mounted on a substrate.

FIG. 2 is a side view, indicated generally by the reference numeral 20, of the circuit of FIG. 1. The view 20 shows how the first connection terminal 11b and second connection terminal 12 are on the same level (e.g. vertical level in the context of the side view 20).

In the leadframe structure of the circuit 10, spatial overlap of terminals is not feasible due to, for example, the manufacturing process (e.g. where a leadframe comprising positive and negative terminals in one piece such that a busbar with overlapping terminals may not be stamped out from a metal plate or leadframe). Furthermore, as the first (negative) connection terminals 11 (11a and 11b) and second (positive) terminals 12 are in the same level (e.g. vertical level), it may not be feasible to connect the first connection terminals 11a and 11b at the level of the leadframe, as the second connection terminal 12 is between the first connection terminals 11a and 11b. In order to connect the first connection terminals 11a and 11b, a separate connection wire may be required. It may be desirable to connect the first connection terminals 11a and 11b during the manufacture of the leadframe in order to make the leadframe more compact, and avoid using additional connections on the circuit. Similarly, if there were a plurality of second connection terminals 12, it may be desirable to connect the plurality of second connection terminals at the leadframe level.

Certain example embodiments, described below, provide a leadframe with at least partially overlapping terminals. Such and embodiment may be an advantage, for example, since overlapping terminals may result in relatively lower inductance, thus yielding relatively lower switching losses. Such a reduction in inductance and consequent reduction in switching losses becomes more and more important when switching frequencies are higher, as they might be when wide-band-gap semiconductors are used. Such technologies are rising in importance.

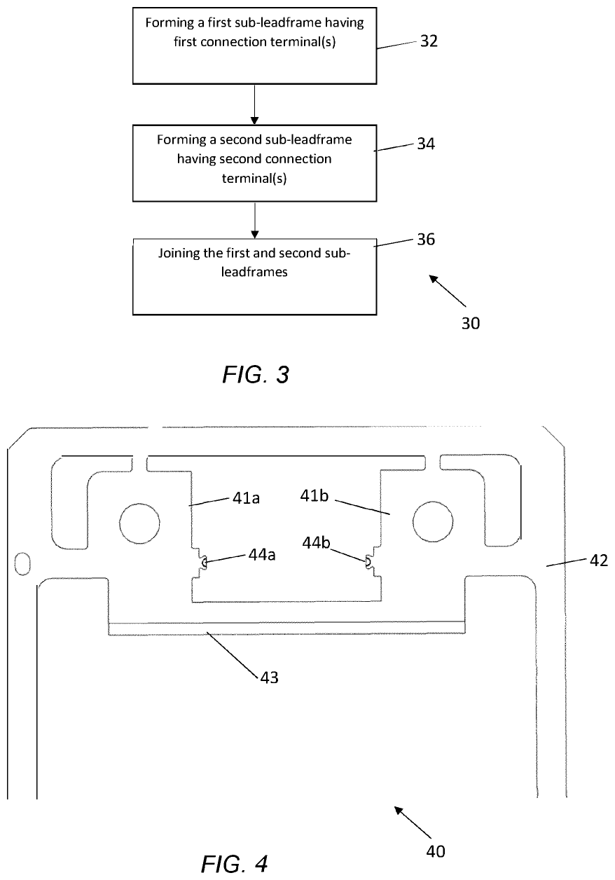

FIG. 3 is a flowchart of an algorithm, indicated generally by the reference numeral 30, in accordance with an example embodiment. The algorithm 30 may be used to manufacture a leadframe according to various example embodiments.

At operation 32, a first sub-leadframe is formed, where the first sub-leadframe may have one or more first connection terminals. At operation 34, a second sub-leadframe, having one or more second connection terminals, is formed. Optionally the second sub-leadframe may include a supporting frame. At operation 36, the first and second sub-leadframes are joined to form a leadframe such that at least some of the first connection terminals overlap at least some of the second connection terminals. This is described in further detail below.

In an example embodiment, the first sub-leadframe further comprises a supporting frame, such that, for example, the first and second sub-leadframe are joined using the supporting frame.

FIG. 4 is a view from above of a first sub-leadframe, indicated generally by the reference numeral 40, in accordance with an example embodiment. FIG. 5 is a three-dimensional view, indicated generally by the reference numeral 50, of the first sub-leadframe 40 in accordance with an example embodiment. The first sub-leadframe 40 may be formed in the operation 32 of the algorithm 30 described with reference to FIG. 3.

The first sub-leadframe 40 comprises one or more first connection terminals 41a and 41b and optionally a supporting frame 42 (e.g. dam bar). The first sub-leadframe 40 further comprises a connection plate 43, such that the first sub-leadframe 40 may connect to one or more circuit elements on a substrate via the connection plate 43. One or more of a number of methods may be used to electrically connect the first sub-leadframe to circuit elements on the substrate. Such methods may include ultrasonic welding, laser welding, sintering, gluing or induction soldering. The connection plate 43 also connects the first connection terminals 41a and 41b at the level of the leadframe, such that no additional connection wires may be required on the circuit in order to connect the first connection terminals 41a and 41b. As discussed further below, the first connection terminals 41a and 41b may be used, for example, as negative DC terminals of a power module.

The first sub-leadframe 40 comprises one or more connection means 44a and 44b, for example, for joining with a second sub-leadframe (such as the second sub-leadframe described in detail below). For example, the first connection terminals 41a and/or 41b may be mechanically joined with one or more second terminals via the connection means 44a and/or 44b respectively. In an example embodiment, connection means 44a and 44b may enable the first sub-leadframe 40 to be joined with a second sub-leadframe by dovetailing. Alternatively, or in addition, the first sub-leadframe may be joined with the second sub-leadframe by welding, gluing, sintering, soldering, or the like.

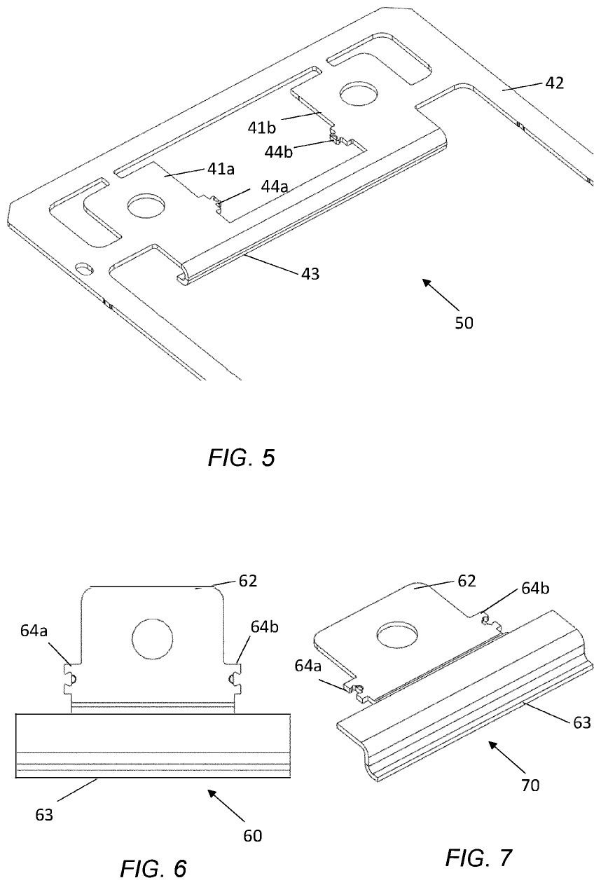

FIG. 6 is a view from above of a second sub-leadframe, indicated generally by the reference numeral 60, in accordance with an example embodiment. FIG. 7 is a three-dimensional view, indicated generally by the reference numeral 70, of the second sub-leadframe 60 in accordance with an example embodiment. The second sub-leadframe 60 may be formed in the operation 34 of the algorithm 30 described above with reference to FIG. 3.

The second sub-leadframe 60 comprises one or more second connection terminal(s) 62. The second sub-leadframe 60 further comprises a connection plate 63, such that the second sub-leadframe 60 may connect to one or more circuit elements on a substrate via the connection plate 63. One or more of a number of methods may be used to electrically connect the second sub-leadframe to circuit elements on the substrate. Such methods may include ultrasonic welding, laser welding, sintering, gluing or induction soldering. In one example embodiment, the connection plate 63 may be used for electrically connecting a plurality of second connection terminals 62 (not shown in FIG. 6) at the level of the leadframe. As discussed further below, the second connection terminal(s) 62 may be used, for example, as a positive DC terminal of a power module.

The second sub-leadframe 60 comprises one or more connection means 64a and 64b, for example, for joining with a first sub-leadframe, such as the first sub-leadframe 40. For example, the second connection terminal 62 may be mechanically joined (e.g. mated) with one or more first connection terminals 41a and 41b via the connection means 64a and 64b respectively. In an example embodiment, the connection means 64a and 64b enable the second sub-leadframe 60 to be joined/mated with the first sub-leadframe 40 by dovetailing. Alternatively, or in addition, the second sub-leadframe 60 may be joined with the first sub-leadframe 40 by welding, gluing, sintering, soldering, or the like.

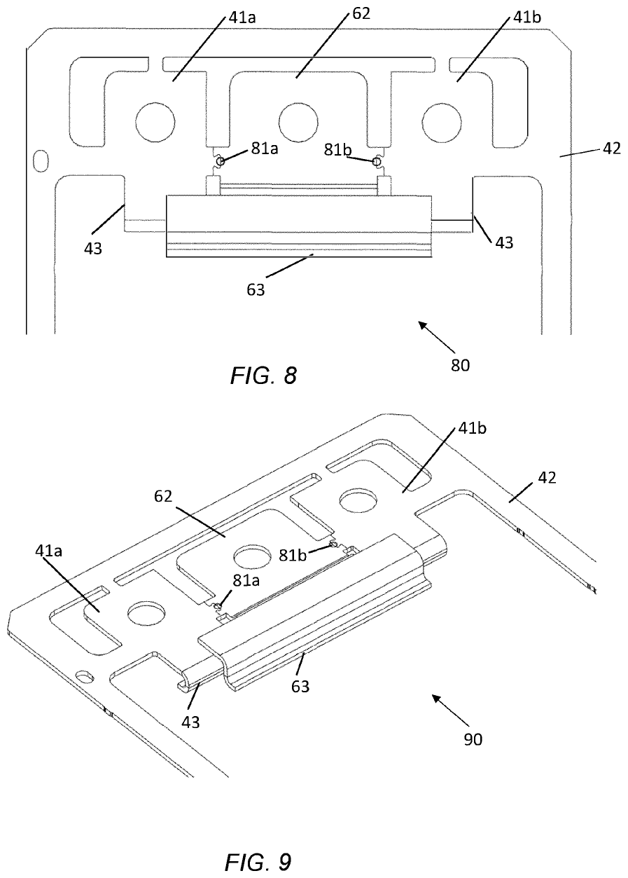

FIG. 8 is a view from above of a leadframe, indicated generally by the reference numeral 80, in accordance with an example embodiment. FIG. 9 is a three-dimensional view, indicated generally by the reference numeral 90, of the leadframe 80 of FIG. 8 in accordance with an example embodiment. The leadframe 80 may be formed by joining the first sub-leadframe 40 and the second sub-leadframe 60 described above.

In the leadframe 80, the first connection terminals 41a and 41b (of the first sub-leadframe 40) are connected to the second connection terminal 62 (of the second sub-leadframe 60) at connections 81a and 81b respectively. As described above with reference to FIGS. 4 and 5, the first connection terminals 41a and 41b are electrically connected at the leadframe via connection plate 43. The connections 81a and 81b may be dovetail connections. As seen in the view 90, there is some overlap between the first sub-leadframe 40 and the second sub-leadframe 60, particularly between the connection plates 43 and 63. For example, overlapping terminals may result in relatively lower inductance, thus yielding relatively lower switching losses.

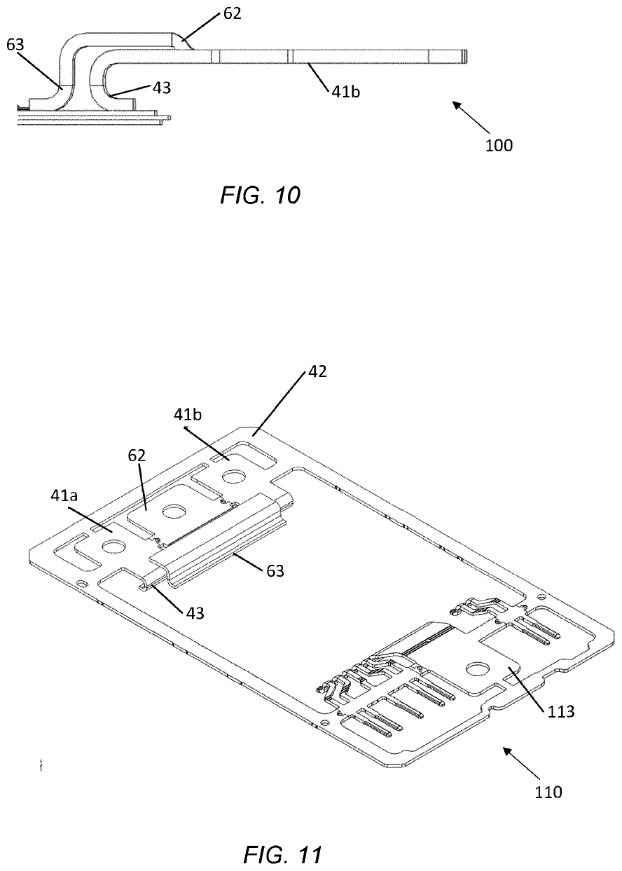

FIG. 10 is a side view of the leadframe 80 of FIG. 8 in accordance with an example embodiment. It can be seen that there the second connection terminal 62 and first connection terminal 41b comprises at least some surface area that is not at the same level of each other, such that the first and second terminals 41b and 62 may have at least some overlap.

FIG. 11 is a three dimensional view of a leadframe, indicated generally with the reference numeral 110, in accordance with an example embodiment. FIG. 11 can be viewed in conjunction with FIGS. 4 to 10 as described above. In one example, at least some of the first connection terminals 41a and 41b are connected to form a first busbar, and at least some of the second connection terminal(s) 62 (only one second connection terminal shown) are connected to form a second busbar. For example, the first connection terminals 41a and 41b may be connected to one or more negative DC inputs, and the second connection terminal(s) 62 may be connected to one or more positive DC inputs. Furthermore, the leadframe 110 may also be connected to one or more AC outputs, for example, via AC terminal 113. For example, the first busbar comprising the first connection terminals 41a and 41b may be a negative busbar, and the second busbar comprising the second connection terminal(s) 62 may be a positive busbar.

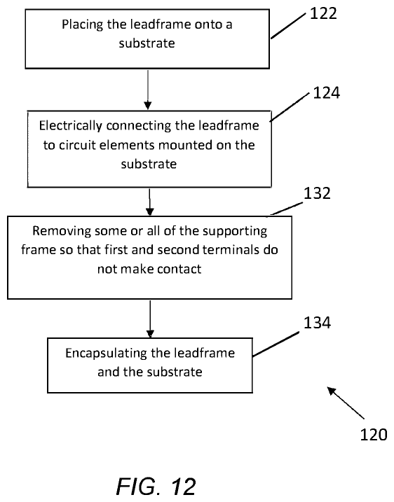

In one example, the first and second busbars may be formed after removing the supporting frame 42 and the mechanical connection between the first and the second connection terminals, as described in further detail below with reference to FIG. 12.

In an example embodiment, the first sub-leadframe 40 and/or the second sub-leadframe 60 may be formed by stamping.

In an example embodiment, the technique described above of joining the first and second sub-leadframes to form a leadframe may provide the benefit of overlapping terminals, and may further provide the ability to stamp out a busbar from the leadframe with overlapping terminals. Furthermore, joining of a plurality of sub-leadframes to form a leadframe may allow the use of different materials or different material thicknesses for one or more of the plurality of sub-leadframes (in contrast with manufacturing a single-piece leadframe).

FIG. 12 is a flowchart of an algorithm, indicated generally by the reference numeral 120, in accordance with an example embodiment. The operations of algorithm 120 may be carried out after two or more sub-leadframes are joined (e.g. in the operation 36 described with reference to FIG. 3) to form a single leadframe. At operation 122, a leadframe, such as the leadframe 80 described with respect to FIGS. 3 and 8, may be placed onto a substrate. At operation 124, the leadframe may be electrically connected to one or more circuit elements mounted on the substrate. As such, the first and second connection terminals are electrically connected to one or more circuit elements on the substrate. One or more of a number of methods may be used to electrically connect the leadframe to the one or more circuit elements on the substrate. Such methods may include ultrasonic welding, laser welding, sintering, gluing or induction soldering.

An additional advantage of the inventive method is that after the plurality of sub-leadframes are joined, the resulting leadframe may be processed as if it is a single leadframe as is known in the prior art. Thus the same assembly equipment may be used to pick and place the leadframe, to connect is to circuit elements mounted on the substrate, and to complete the finished module, as would be in prior art methods. No extra step are required in the assembly of the module parts in the encapsulation press, for example. This is in contrast to some prior art methods of assembling modules comprising overlapping connection terminals in which two separate sub-leadframes are placed within the molding press in two separate steps with the consequent longer process time, complexity, and expense that such steps involve.

At operation 132, some or all of the supporting frame (e.g. supporting frame 42) is removed, such that the first and second connection terminals of the leadframe do not make physical or electrical contact. The connections 81a and 81b are also removed in order to ensure that the first and second connection terminals do not make physical or electrical contact. For example, the supporting frame may be removed by cutting away material. Such material may be any material that will remain unencapsulated after the subsequent encapsulation step (see below) and which does not form part of the first or second connection terminals.

At operation 134, the leadframe (e.g. leadframe 80) and the substrate (e.g. on which the leadframe 80 is placed in operation 122) may be encapsulated, leaving the first and second connection terminals exposed.

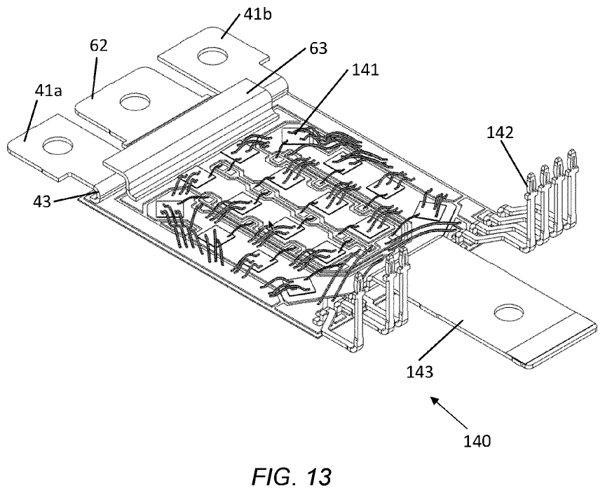

FIG. 13 is three-dimensional view of a circuit (e.g. a power module), indicated generally by the reference numeral 140, in accordance with an example embodiment. The circuit 140 may be generated using the operations described with reference to FIGS. 3 and 12.

The circuit 140 comprises one or more first connection terminals 41a and 41b, one or more second connection terminal(s) 62 (a single such second terminal is shown in FIG. 13), connection plates 43 and 63, one or more circuit elements 141, DC connections 142, and an AC terminal 143. In one example, the circuit 140 may be a power module comprising a leadframe (e.g. leadframe 80), a substrate onto which the leadframe is placed, and encapsulation material (not shown) encapsulating the leadframe and the substrate, comprising circuit elements electrically connected to said substrate, leaving the first and second connection terminals exposed.

As shown in FIG. 13, the supporting frame 42 described above has been removed, such that the first and second connection terminals are not electrically or physically connected. The one or more circuit elements are shown to be mounted on a substrate, and the first connection terminals 41a and 41b may be connected to each other and/or the substrate via the connection plate 43, and second connection terminal(s) 62 may be connected to each other and/or the substrate via the connection plate 63. In one example, the contacts 142 may be used for connecting to control inputs and/or control outputs.

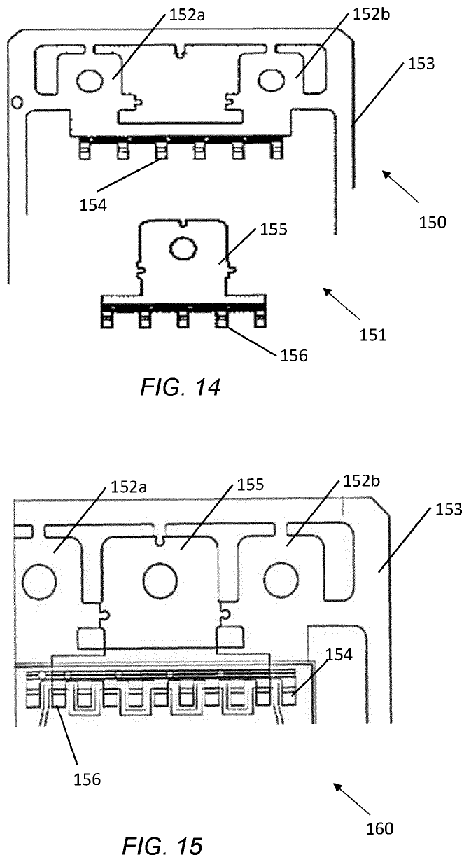

FIG. 14 is a view from above of first and second sub-leadframes, indicated generally by reference numerals 150 and 151 respectively, in accordance with an example embodiment. The first sub-leadframe 150 may comprise first connection terminals 152a and 152b (e.g. similar to first connection terminals 41a and 41b), and supporting frame 153 (e.g. similar to the supporting frame 42). One or more of the first connection terminals 152a and 152b comprises a plurality of first fingers 154. The second sub-leadframe 151 may comprise one or more second connection terminal(s) 155 (e.g. similar to the second connection terminal 62). One or more of the second connection terminal(s) 155 comprises a plurality of second fingers 156. The first and second fingers 154 and 156 may extend towards the substrate. The first and second sub-leadframes 150 and 151 may be joined to form a leadframe, as shown and described in further detail below with respect to FIG. 15.

FIG. 15 is a view from above of part of a leadframe, indicated generally with the reference numeral 160, in accordance with an example embodiment. The first and second sub-leadframes 150 and 151 are joined such that the first fingers 154 and the second fingers 156 are provided in an alternating pattern (e.g. DC positive-negative-positive-negative arrangement). For example, the alternating pattern of the first and second fingers may lower terminal area (e.g. compared to the arrangement of the plates 43 and 63) and may in turn lower inductance. In one example, the encapsulating material (e.g. mold) may have better access to the space between the overlapping parts of the first and second connection terminals 152 (152a, 152b) and 155, thus making it easier to provide insulation between the terminals. Such a finger pattern may also make it easier to access the contacts between the leadframe and the circuit elements mounted on the substrate, should connection methods such as ultrasonic welding, laser welding, sintering, gluing or other methods that may need such access, are used for making such connections.

In an example embodiment, the method for manufacturing leadframes, as described above with reference to FIGS. 3 to 15 may also be used for control or signal connections where lower voltage signals may be provided to gate connections of switching conductors. In another example, the leadframe formed may comprise a plurality of layers (e.g. double layer lead), which may further reduce inductance.

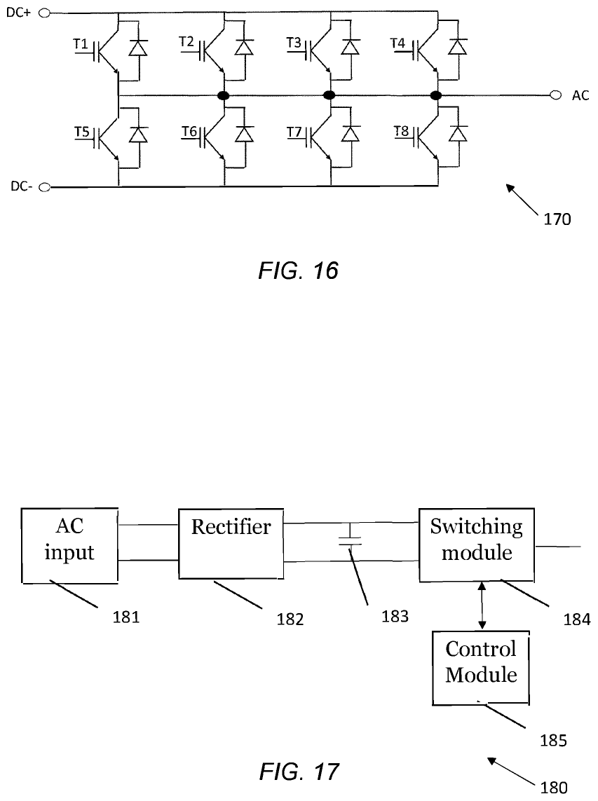

FIG. 16 is a circuit diagram of an example inverter circuit, indicated generally by the reference numeral 170, that may be used to provide the switching circuitry of a semiconductor power module, for example as described above with reference to FIG. 14. Circuit 170 comprises a plurality of switching elements connected in parallel, with a positive DC terminal (e.g. DC terminals 41a, 41b), a negative DC terminal (e.g. DC terminal 62), and an AC terminal (e.g. AC terminal 33, 83). The skilled person will be aware of many alternative circuits that could be used.

FIG. 17 is a block diagram of an inverter circuit, indicated generally by the reference numeral 180, in which power modules in accordance with the principles described herein may be used. The inverter circuit 180 comprises an AC input 181, a rectifier 182 for converting an AC power source into a DC signal, and a DC storage capacitor 183. The inverter circuit further comprises a switching module 184 and a control module 185 for controlling the switching of the plurality of switching components of the switching module 184. The circuits described above may be used to implement the switching module 184, with the DC voltage across the DC storage capacitor providing the DC inputs to the busbars.

The embodiments of the invention described above are provided by way of example only. The skilled person will be aware of many modifications, changes and substitutions that could be made without departing from the scope of the present invention. The claims of the present application are intended to call all such modifications, changes and substitutions as fall within the spirit and scope of the invention.

What is claimed is:

1. A method comprising:
forming a first sub-leadframe having one or more first connection terminals;
forming a second sub-leadframe having one or more second connection terminals;
joining the first and second sub-leadframes to form a leadframe such that at least some of the first connection terminals overlap at least some of the second connection terminals.

2. The method as claimed in claim 1, wherein the first sub-leadframe further comprises a supporting frame, wherein the first and second sub-leadframe are joined using the supporting frame.

3. The method as claimed in claim 1, wherein at least some of the first connection terminals are connected to form a first busbar.

4. The method as claimed in claim 1, wherein at least some of the second connection terminals are connected to form a second busbar.

5. The method as claimed in claim 1, wherein the first and second sub-leadframes are joined by dovetailing.

6. The method as claimed in claim 1, wherein the first sub-leadframe and/or the second sub-leadframe is/are formed by stamping.

7. The method as claimed in claim 1, further comprising:
placing the leadframe onto a substrate; and
electrically connecting the leadframe to circuit elements mounted on the substrate.

8. The method as claimed in claim 5, further comprising:
encapsulating the leadframe and the substrate, leaving the first and second connection terminals exposed.

9. The method as claimed in claim 2, further comprising:
removing some or all of the supporting frame such that the first and second connection terminals of the leadframe do not make physical or electrical contact.

10. The method as claimed in claim 1 wherein:
one of the first connection terminals comprises a plurality of first fingers;
one of the second connection terminals comprises a plurality of second fingers; and
the first and second fingers are provided in an alternating pattern.

11. A leadframe comprising:
a first sub-lead frame comprising one or more first connection terminals;
a second sub-lead frame comprising one or more second connection terminals,
wherein the first and second sub-leadframes are joined such that at least some of the first connection terminal overlap at least some of the second connection terminals.

12. The leadframe as claimed in claim 11, wherein the first sub-leadframe further comprises a supporting frame, wherein the first and second sub-lead-frame are joined using the supporting frame.

13. The leadframe as claimed in claim 11, wherein:
at least some of the first connection terminals of the leadframe are connected to form a first busbar; and/or
at least some of the second connection terminals of the leadframe are connected to form a second busbar.

14. The leadframe as claimed in claim 11, where:
one of the first connection terminals comprises a plurality of first fingers;
one of the second connection terminals comprises a plurality of second fingers; and
the first and second fingers are provided in an alternating pattern.

15. The leadframe as claimed in claim 12, wherein some or all of the supporting frame is configured to be removed such that the first and second connection terminals of the leadframe do not make physical or electrical contact.

16. A power module comprising:
a leadframe as claimed in claim 11; and
a substrate onto which the leadframe is placed, wherein the substrate comprises circuit elements electrically connected to said substrate.

17. The power module as claimed in claim 16, further comprising an encapsulation material encapsulating the leadframe and the substrate, leaving the first and second connection terminals exposed.

18. A computer-readable medium having computer executable instructions adapted to cause a 3D printer or additive manufacturing apparatus to form some or all of an apparatus according to the method as described in claim 1, a leadframe comprising a first sub-lead frame comprising one or more first connection terminals, a second sub-lead frame comprising one or more second connection terminals, wherein the first and second sub-leadframes are joined such that at least some of the first connection terminal overlap at least some of the second connection terminals, or a power module comprising the leadframe and a substrate onto which the leadframe is placed, wherein the substrate comprises circuit elements electrically connected to said substrate.
